(19) United States
(12) Patent Application Publication
(10) Pub. No.: US 2016/0126456 A1
(43) Pub. Date: May 5, 2016

(54) DONOR SUBSTRATE

(71) Applicant: Samsung Display Co., Ltd., Yongin-city (KR)

(72) Inventor: Young Gil KWON, Suwon-si (KR)

(21) Appl. No.: 14/695,405

(22) Filed: Apr. 24, 2015

(30) Foreign Application Priority Data
Nov. 5, 2014 (KR) 10-2014-0152905

(51) Int. Cl. H01L 51/00; H01L 51/56

(52) U.S. Cl. CPC H01L 51/0013; H01L 51/56

(57) ABSTRACT

A donor substrate including: a light-transmitting base substrate; an insulation layer disposed on an upper surface of the light-transmitting base substrate, the insulating layer including: a first area having a first thickness; a second area having a second thickness, the second thickness different from the first thickness; and a third area having a third thickness, the third thickness different from the first thickness and the second thickness; an absorption layer disposed on the insulation layer; and a transfer layer disposed on the absorption layer.

### CROSS-REFERENCE TO RELATED APPLICATION

This application claims priority from and the benefit of Korean Patent Application No. 10-2014-0152905 filed on Nov. 5, 2014, and all the benefits accruing therefrom under 35 U.S.C. 119, the contents of which in its entirety are herein incorporated by reference.

### BACKGROUND

1. Field

Exemplary embodiments relate to a donor substrate and a method of manufacturing a display device by using the donor substrate.

2. Discussion of the Background

An organic light emitting display device, which is a self-light-emitting type display device, has a wide view angle, a good contrast, and a high response speed, thereby drawing attention as a next-generation display device.

Generally, an organic electro-luminescence device includes an anode electrode and a cathode electrode, and organic films which are interposed between the anode electrode and the cathode electrode. The organic films include at least an auxiliary layer and may also include a hole injection layer, a hole transport layer, an electron transport layer, and an electron injection layer. The organic electro-luminescence device may be a high molecular organic electro-luminescence device and a low molecular organic electro-luminescence device, depending on the materials forming the organic film, particularly, the auxiliary layer.

An organic electro-luminescence device may include the auxiliary layer patterned to improve the color purity and light emission efficiency of a full-color organic electro-luminescence device. For example, the auxiliary layer may be patterned by a method of using a fin metal mask for the low molecular organic electro-luminescence device, and a method of an inkjet printing and/or laser-induced thermal imaging (LITI) method for the high molecular organic electro-luminescence device.

The LITI is a dry process in which the organic film may be fine-patterned, and the inkjet printing is a wet process.

According to a method of forming a pattern of a high molecular organic film by the LITI, the method includes at least a light source, an organic electro-luminescence device substrate, i.e., a device substrate (also called an insulating substrate), and a donor substrate. Here, the donor substrate may include a transfer layer, a base substrate, a reflection pattern layer, an insulation layer, an absorption layer, an organic film, etc. An organic layer may be patterned onto the device substrate from the donor substrate by using the light source radiating light onto the absorption layer of the substrate, the absorption configured to convert the light into heat energy, and the generated heat deposits the organic layer onto the device substrate to form the transfer layer, is deposed on the device substrate by the heat energy.

The above information disclosed in this Background section is only for enhancement of understanding of the background of the inventive concept, and, therefore, it may contain information that does not form the prior art that is already known in this country to a person of ordinary skill in the art.

### SUMMARY

Exemplary embodiments provide a donor substrate including an insulation layer having differential thicknesses.

Exemplary embodiments provide a donor substrate including an insulation layer having differential thermal conductivities.

Exemplary embodiments provide a method of manufacturing a display device using a donor substrate including an insulating layer having differential thicknesses.

Additional aspects will be set forth in the detailed description which follows, and, in part, will be apparent from the disclosure, or may be learned by practice of the inventive concept.

According to one or more exemplary embodiments, a donor substrate includes: a light-transmitting base substrate; an insulation layer disposed on an upper surface of the light-transmitting base substrate, the insulating layer including: a first area having a first thickness; a second area having a second thickness, the second thickness different from the first thickness; and a third area having a third thickness, the third thickness different from the first thickness and the second thickness; an absorption layer disposed on the insulation layer; and a transfer layer disposed on the absorption layer.

According to one or more exemplary embodiments, a donor substrate includes: a light-transmitting base substrate; an insulation layer disposed on an upper surface of the light-transmitting base substrate, the insulating layer including: a first area including a first material; a second area including a second material, the second material different from the first material; and a third area including a third material, the third material different from the first material and the second material; an absorption layer disposed on the insulation layer; and a transfer layer disposed on the absorption layer.

According to one or more exemplary embodiments, a method pf manufacturing a display device includes: preparing a donor substrate including: a light-transmitting base substrate; an insulation layer disposed on an upper surface of the light-transmitting base substrate, the insulating layer including: a first area having a first thickness; a second area having a second thickness, the second thickness different from the first thickness; and a third area having a third thickness, the third thickness different from the first thickness and the second thickness; an absorption layer disposed on the insulation layer; and a transfer layer disposed on the absorption layer, disposing a pixel insulation substrate facing an upper surface of the donor substrate; and depositing at least a part of the transfer layer onto the pixel insulation substrate to form an auxiliary layer by radiating light through a lower surface of the light-transmitting base substrate.

### BRIEF DESCRIPTION OF THE DRAWINGS

The accompanying drawings, which are included to provide a further understanding of the inventive concept, and are incorporated in and constitute a part of this specification, illustrate exemplary embodiments of the inventive concept, and, together with the description, serve to explain principles of the inventive concept.

FIG. 1 is a cross-sectional view of a donor substrate according to one or more exemplary embodiments.

FIGS. 2, 3, 4, and 5 illustrate a method of manufacturing a display device according to one or more exemplary embodiments.

FIGS. 6, 7, 8, and 9 are cross-sectional views of a donor substrate according to one or more exemplary embodiments.

FIG. 10 is a cross-sectional view of a donor substrate according to one or more exemplary embodiments.

FIG. 11 is a cross-sectional view of a transfer process using the donor substrate illustrated in FIG. 10 according to one or more exemplary embodiments.

FIGS. 12, 13, 14, and 15 are cross-sectional views of a donor substrate according to one or more exemplary embodiments.

### DETAILED DESCRIPTION OF THE ILLUSTRATED EMBODIMENTS

In the following description, for the purposes of explanation, numerous specific details are set forth in order to provide a thorough understanding of various exemplary embodiments. It is apparent, however, that various exemplary embodiments may be practiced without these specific details or with one or more equivalent arrangements. In other instances, well-known structures and devices are shown in block diagram form in order to avoid unnecessarily obscuring various exemplary embodiments.

In the accompanying figures, the size and relative sizes of layers, films, panels, regions, etc., may be exaggerated for clarity and descriptive purposes. Also, like reference numerals denote like elements.

When an element or layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. Like numbers refer to like elements throughout. As used herein, the term “and/or” includes any and all combinations of one or more of the associated listed items.

Although the terms first, second, etc. may be used herein to describe various elements, components, regions, layers, and/or sections, these elements, components, regions, layers, and/or sections should not be limited by these terms. These terms are used to distinguish one element, component, region, layer, and/or section from another element, component, region, layer, and/or section. Thus, a first element, component, region, layer, and/or section discussed below could be termed a second element, component, region, layer, and/or section without departing from the teachings of the present disclosure.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Various exemplary embodiments are described herein with reference to plan and/or sectional illustrations that are schematic illustrations of idealized exemplary embodiments and/or intermediate structures. As such, variations from the shapes of the illustrations as a result, for example, of manufacturing techniques and/or tolerances, are to be expected. Thus, u) exemplary embodiments disclosed herein should not be construed as limited to the particular illustrated shapes of regions, but are to include deviations in shapes that result from, for instance, manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and will not be interpreted in an idealized or overly formal sense, unless expressly so defined herein.

Hereinafter, embodiments of the present invention will be described with reference to the attached drawings.

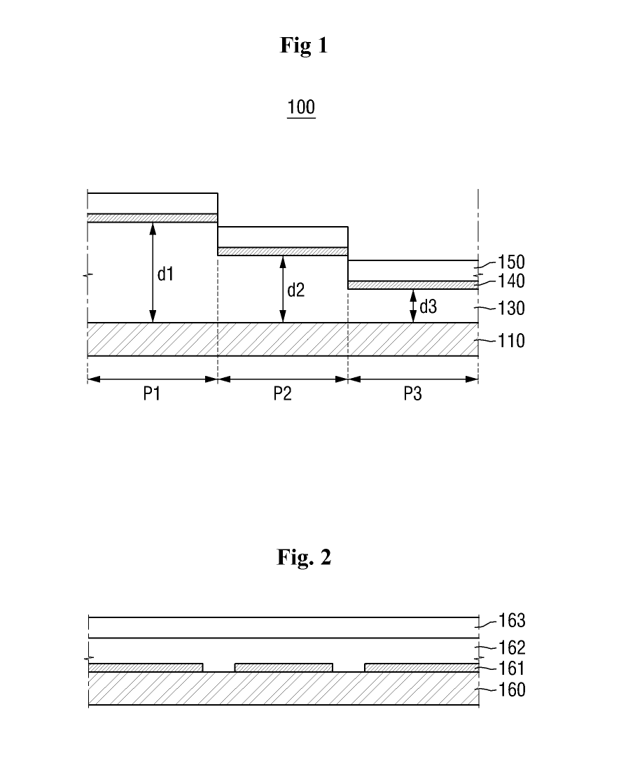

FIG. 1 is a cross-sectional view of a donor substrate according to one or more embodiments.

Referring to FIG. 1, a donor substrate 100 according to exemplary embodiments may include a light-transmitting base substrate 110, an insulation layer 130, an absorption layer 140, and a transfer layer 150.

The light-transmitting base substrate 110 may transmit lamp light or laser light from a light source. Hence, the light-transmitting base substrate 110 may be a light-transmitting substrate configured to transmit lamp light or laser light. For example, the light-transmitting base substrate 110 may be a synthetic resin substrate made of transparent high molecular materials including at least one of polyester, poly-acryl, poly-epoxy, polyethylene, polystyrene, and polyethylene terephthalate.

The insulation layer 130 is disposed on one surface of the light-transmitting base substrate 110. The insulation layer 130 is divided into a first area P1 having a first thickness d1, a second area P2 having a second thickness d2 different from the first thickness d1, and a third area P3 having a third thickness d3 different form the first thickness d1 and the second thickness d2. The first thickness d1 in the first area P1 may be greater than the second thickness d2 and the third thickness d3, and the second thickness d2 in the second area P2 may be greater than the third thickness d3.

The upper surfaces of the insulation layer 130 may be flat at different heights according to the corresponding areas. Specifically, a step may be formed on the upper surface of the insulation layer 130 between the first area P1 and the second area P2, and a step may be formed on the upper surface of the insulation layer 130 between the second area P2 and the third area P3.

The insulation layer 130 may include at least one of titanium oxide, silicon oxide, silicon nitride oxide, zirconium oxide, silicon carbide, silicon oxide, silicon nitride, and an organic polymer, but embodiments are not limited thereto. The insulation layer 130 may be deposited using a sputtering method, an electronic beam deposition method, a vacuum deposition method, and the like.

The absorption layer 140 is disposed on the insulation layer 130. The absorption layer 140 may be a light-heat conversion layer configured to absorb light transmitted through the light-transmitting base substrate 110 and the insulation layer 130, and convert the absorbed light into heat energy. The absorption layer 140 may include material having a low light reflectivity and a high light absorption rate. For example, the absorption layer 140 may include at least one of molybdenum (Mo), Chrome (Cr), Titanium (Ti), tin (Sn), tungsten (W), an alloy containing them, and the like. The absorption layer 140 may be deposited using a sputtering method, an electronic beam deposition method, a vacuum deposition method, and/or the like.

The transfer layer 150 is disposed on the absorption layer 140. The transfer layer 150 may include at least one of organic materials, inorganic materials, or organic metal. Specifically, for example, the organic materials may include at least one of poly (phenylenevinylene), poly-para-phenylene, polyfluorene, polydialkylfluorene, polthiophene, poly (9-vinylcarbazole), poly (N-vinylcarbazole-vinyl alcohol) copolymer, triarylamine, polynorbornene, polyaniline, polyaryl polyarmine, and triphenylamine-polyetherketone. The inorganic materials may include at least one of SiNx, SiOx, and SiON.

The transfer layer 150 may include at least one of known light-emitting materials, hole transfer type organic materials, and electron transfer type organic materials according to characteristics of a display device, and may further includes a compound including at least one of non-light-emitting low molecular materials, non-light-emitting electron transfer polymer materials, and curable organic binder materials.

The transfer layer 150 may be formed by, but not limited to, a wet method including a spin coat method, a spray coat method, an inkjet method, a deep coat method, a cast method, a dye coat method, a roll coat method, a blade coat method, a bar coat method, a gravure coat method, and a printing method, and/or a dry method including a vacuum deposition method and a sputtering method.

According to one or more exemplary embodiments, the insulation layer 130 may have different thicknesses according to the corresponding areas, and thus may control the sublimation level and the deposition thickness of the transfer layer 150 differently in different areas.

Specifically, the first thickness d1 of the insulation layer 130 in the first area P1 is larger than the second and third thicknesses d2 and d3 of the insulation layer 130 in the second area P2 and the third area P3, and thus, the insulation effects of the insulation layer 130 may be greater in the first area P1 than the second area P2 and the third area P3. Hence, when the absorption layer 140 absorbs light energy and converts the light energy into heat energy, the insulation layer 130 in the first area P1 may block more heat energy from begin discharged to the light-transmitting base substrate 110 compared to the second area P2 and the third area P3, and thus, may transfer relatively more heat energy to the transfer layer 150. Hence, the transfer layer 150 may be sublimated more in the first area P1 compared to the second area P2 and the third area P3.

In the same manner, the insulation layer 130, which is formed in the second area P2, has a thickness greater than that of the insulation layer 130 which is formed in the third area P3, and thus, more transfer layers 150 may be sublimated in the second area P2 compared to the third area P3. As a result, the thicknesses of the transfer layers deposited on the substrate may be controlled to be different according to the corresponding areas.

Hereinafter, the method of manufacturing a display device using an optical mask will be described. An organic light-emitting display device is used as an example of a display device for explanation convenience purpose.

FIGS. 2, 3, 4, and 5 illustrate a method of manufacturing a display device according to one or more exemplary embodiments.

Referring to FIG. 2, an anode 161 is disposed corresponding to each pixel on the insulating layer 160. According to one or more exemplary embodiments, the anode 161 may directly contact the insulation layer 160, or materials such as an insulation layer may be disposed between the anode 161 and the insulation layer 160.

The anode 161 may include conductive materials having a high work function. When the organic light-emitting display device is a backward emitting display device, the anode 161 may include a reflective film including at least one of Silver (Ag), Magnesium (Mg), Aluminum (Al), Platinum (Pt), Magnesium (Pd), Gold (Au), Nickel (Ni), Neodymium (Nd), Iridium (Ir), Chromium (Cr), Lithium (Li), Calcium (Ca), and the like. The anode 161 may have a structure of multiple layers including two or more materials and may be modified in various manners. For example, the anode 161 may be formed through a sputtering process using a fine metal mask (FMM).

Thereafter, a hole injection layer 162 and a hole transfer layer 163 are disposed on the anode 161. The hole injection layer 162 may be disposed on a plurality of anodes 161. Specifically, the hole injection layer 162 may be interposed between the plurality of anodes 161 and the hole transfer layer 163. The hole injection layer 162 may be disposed separately for respective pixels, or the hole injection layer 162 may be formed as a single integrated layer throughout the entire surface of the insulation substrate 160 as illustrated in FIG. 2. That is, the hole injection layer 162 may be formed as a common layer unrelated with the distinction of pixels. The hole injection layer 162 may be commonly formed on a plurality of pixel areas. According to exemplary embodiments, the hole injection layer 162 may be omitted.

The hole injection layer 162 is a buffering layer configured to lower the energy wall between the anode 161 and the hole transfer layer 163, and aid the hole provided from the anode 161 to be introduced into the hole transfer layer 163. The hole injection layer 162 may be formed of an organic compound including at least one of, but not limited to, MTDATA (4,4′,4″-tris(3-methylphenylphenylamino)triphenylamine), CuPc (copper phthalocyanine), and PEDOT/PSS (poly(3,4-ethylenedioxythiphene, polystyrene sulfonate).

The hole transfer layer 163 may be disposed on the hole injection layer 162. Specifically, the hole transfer layer 163 may be interposed between the hole injection layer 162 and a plurality of light-emitting layers 151a, 151b, and 151c (refer to FIG. 4). The hole transfer layer 163 may be configured to aid transferring of the hole from the hole injection layer 162 to a plurality of auxiliary layers R′ and G′ and the plurality of light-emitting layers 151a, 151b, and 151c. The hole transfer layer 163 may be disposed separately for respective pixels, or the hole transfer layer 163 may be formed as a single integrated layer throughout the entire surface of the insulation substrate 160 as illustrated in FIG. 2. That is, the hole transfer layer 163 may be formed as a common layer unrelated with the distinction of pixels. The hole transfer layer 163 may be commonly formed on a plurality of pixel areas. According to exemplary embodiments, the hole transfer layer 163 may be omitted.

The hole transfer layer 163 may include known hole transfer materials. For example, the hole transfer layer 163 may be include at least one of, but not limited to, 1,3,5-tricarbazolylbenzene, 4,4′-biscarbazolylbiphenyl, polyvinylcarbazol, m-biscarbazolylphenyl, 4,4′-biscarbazolyl-2,2′-dimethylbiphenyl, 4,4′,4″-tri(N-carbazolyl)triphenylamine, 1,3,5-tri(2-carbazolylphenyl)benzene, 1,3,5-tris(2-carbazolyl-5-methoxyphenyl)benzene, bis(4-carbazolylphenyl)silane, N,N′-bis(3-methylphenyl)-N,N′-diphenyl-[1,1-biphenyl]-4,4′diamine (TPD), N,N′-di(naphthalene-1-yl)-N,N′-diphenyl benzidine (NPD), N,N′-diphenyl-N,N′-bis(1-naphthyl)-(1,1′-biphenyl)-4,4′-diamine (NPB), poly(9,9-dioctylfluorene-co-N-(4-butylphenyl)diphenylamine)(poly(9,9-dioctylfluorene-co-N-(4-butylphenyl)diphenylamine) (TFB), poly(9,9-dioctylfluorene-co-bis-N,N-phenyl-1,4-phenylenediamine(poly(9,9-dioctylfluorene-co-bis-(4-butylphenyl-bis-N,N-phenyl-1,4-phenylenediamin) (PFB), and the like

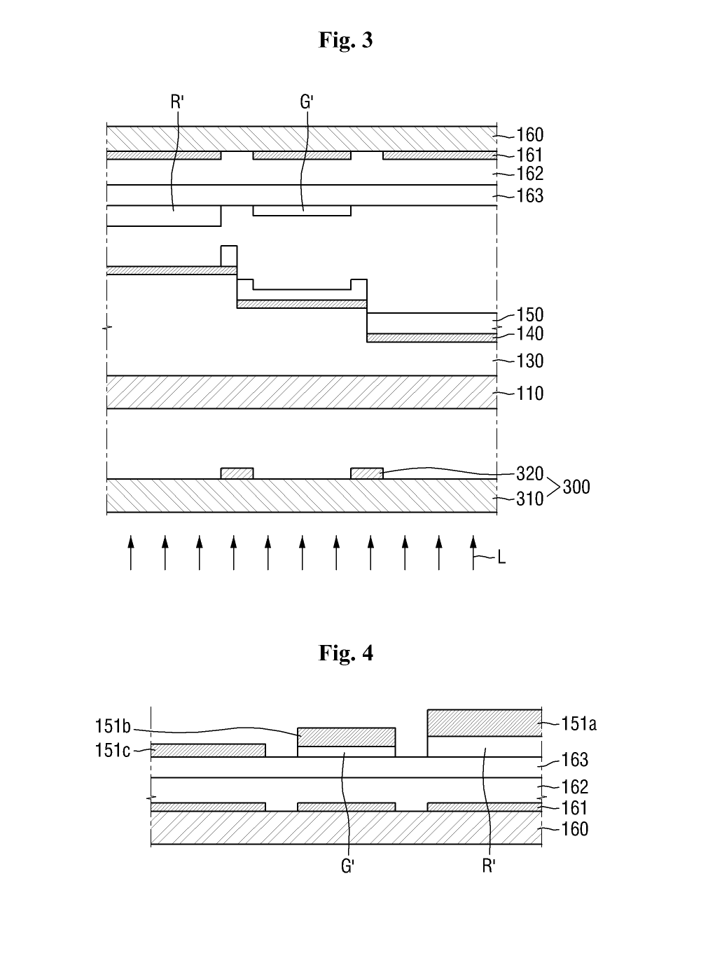

Referring to FIG. 3, auxiliary layers R′ and G′ are disposed on the hole transfer layer 163. Specifically, the donor substrate 100 is closely arranged on the insulation layer 160 where the hole injection layer 162/hole transfer layer 163 is disposed. Each area of the donor substrate 100 may be arranged to correspond to each pixel on the insulating layer 160. For example, the first area of the donor substrate 100 may correspond to the red pixel of the insulating layer 160, the second area of the donor substrate 100 may correspond to the green pixel of the insulating layer 160, and the third area of the donor substrate 100 may correspond to the blue pixel of the insulating layer 160.

The optical mask 300 including the light-transmitting area and a shade part 320 is arranged, and light is radiated. The optical mask 300 includes a shade part 320 which is disposed on the mask base 310 and a light-transmitting area configured to transmit light formed between the shade parts 320.

Referring to FIG. 3, light radiates through the light-transmitting area of the optical mask and onto the absorption layer 140 of the optical mask, which is in turn configured to generate heat energy. The generated heat energy may sublimate the transfer layer 150 disposed on the upper surface of the absorption layer 140. Due to the thick insulation layer 130 in the first area P1, heat generated by the absorption layer 140 in the first area P1 may be transmitted to the transfer layer 150 to the transfer layer 150 with less leakage of heat energy toward the light-transmitting base substrate 110. In the second area P2, the thickness of the insulation layer 130 is less than the first area P1, and thus, the heat energy transferred to the transfer layer 150 onto the transfer layer 150 disposed on the upper surface of the absorption layer 140 may be less than that in the first area P1. Hence, the amount of organic materials sublimated in the first area P1 may be greater than the second area P2, and accordingly, the thickness of the auxiliary layers R′ and G′ deposited on the hole transfer layer 163 may have greater thickness in the area corresponding to the first area P1 than the area corresponding to the second area P2.

The insulation layer 130 in the third area P3 may be relatively thin, and thus the amount of heat energy leaked toward the light-transmitting base substrate 110 may be relatively large, and the amount of heat energy transferred to the transfer layer 150 may be relatively small. The total amount of heat energy transmitted to the transfer layer 150 in the third area P3 may not exceed the threshold for sublimating organic materials and the transfer layer 150 may not be sublimated. Accordingly, the auxiliary layers may not be formed on the insulation substrate 160 corresponding to the third area P3.

Referring to FIG. 4, a plurality of auxiliary layers R′ and G′ may be configured to adjust the resonance cycle of light emitted from a plurality of light-emitting layers 151a, 151b, and 151c. In other words, a plurality of auxiliary layers R′ and G′ may be configured to improve the color purity and light emission efficiency of the plurality of light-emitting layers 151a, 151b, and 151c.

The plurality of auxiliary layers R′ and G′ may include a first auxiliary layer R′ and a second auxiliary layer G′.

The first auxiliary layer R′ may be disposed corresponding to the first area P1. Further, the first auxiliary layer R1 may be interposed between the first light-emitting layer 151a and the hole transfer layer 163. The first auxiliary layer R′ may have a thickness configured to adjust the resonance cycle of light emitted from the first light-emitting layer 151a. The first auxiliary layer R′ may include the same material as the hole injection layer 162 and/or the hole transfer layer 163, but is not limited thereto.

The second auxiliary layer G′ may be disposed corresponding to the second area P2. Further, the second auxiliary layer G′ may be interposed between the second light-emitting layer 151b and the hole transfer layer 163. The second auxiliary layer G′ may have a thickness configured to adjust the resonance cycle of light emitted from the second light-emitting layer 151b. In exemplary embodiments, the thickness of the second auxiliary layer G′ may be greater than the thickness of the first auxiliary layer R′, corresponding to the difference in the resonance cycle of light. The second auxiliary layer G′ may include the same material as the hole injection layer 162 and/or hole transfer layer 163, but is not limited thereto. For example, the second auxiliary layer G′ may be formed of the same material as the first auxiliary layer R′.

Referring to FIG. 4, the plurality of light-emitting layers 151a, 151b, and 151c are formed.

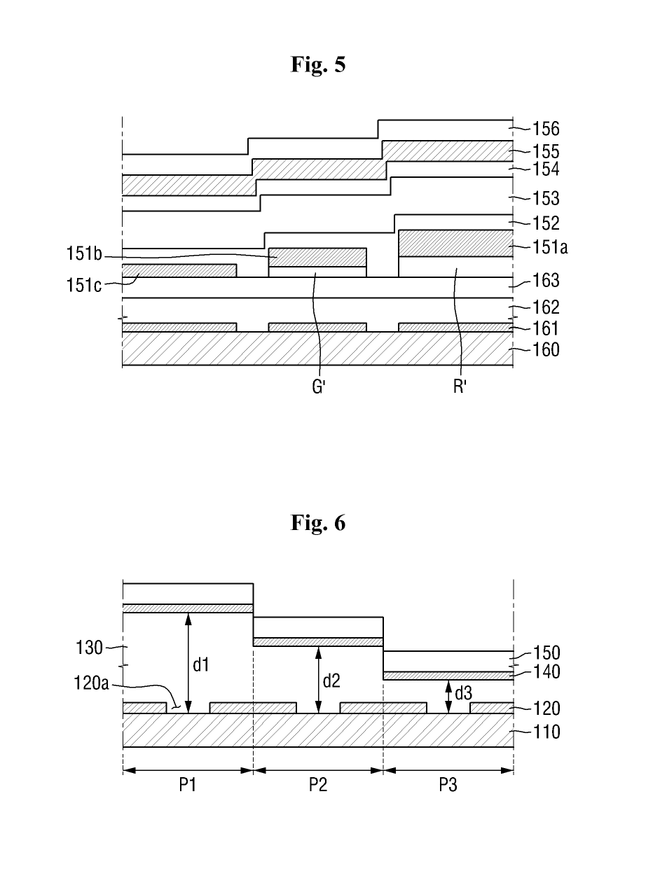

The first light-emitting layer 151a may be interposed between the first auxiliary layer R′ and the buffer layer 152 illustrated in FIG. 5. The first light-emitting layer 151a may include phosphorescene emission materials and/or fluorescent emission materials. For example, the first light-emitting layer 151a may include red phosphorescene emission materials, but the exemplary embodiments are not limited thereto. The first light-emitting layer 151a may contain other color phosphorescene emission materials.

The first light-emitting layer 151a may include polymer materials, low molecular organic materials, and/or mixtures of polymer and low molecular materials, which includes red emission color. According to the exemplary embodiments, the first light-emitting layer 151a may include red host materials and red dopant materials.

The red host materials may include at least one of anthracene derivatives and carbazol compounds, but embodiments are not limited thereto. For example, the anthracene derivatives may include 9,10-(2-di naphthyl)anthracene (ADN), and the carbazol compound may include 4,4′-(carbazol-9-yl) biphenyl (CBP). The red dopant material may include [4-(dicyanomethylene)-2-t-butyl-6-(1,1,7,7-tetramethyljulolidyl-9-enyl)-4H-pyran (4-(dicyanomethylene)-2-t-butyl-6-(1,1,7,7-tetramethyljulolidyl-9-enyl)-4H-pyran; DCJTB)], but the exemplary embodiments are not limited thereto.

The first light-emitting layer 151a may be formed by, but not limited to, a wet method including a spin coat method, a spray coat method, an inkjet method, a deep coat method, a cast method, a dye coat method, a roll coat method, a blade coat method, a bar coat method, a gravure coat method, and a printing method and a dry method including a vacuum deposition method and a sputtering method.

The second light-emitting layer 151b may be interposed between the second auxiliary layer G′ and the buffer layer 152 of FIG. 5. The second light-emitting layer 151b may contain phosphorescene emission materials or fluorescent emission materials. For example, the second light-emitting layer 151b may include green phosphorescene emission materials, but the exemplary embodiments are not limited thereto. The second light-emitting layer 151b may contain other color phosphorescene emission materials.

The second light-emitting layer 151b may include polymer materials, low molecular organic materials, and/or mixtures of polymer and low molecular materials, which includes green emission color. According to the exemplary embodiments, the second light-emitting layer 151b may include green host materials and green dopant materials.

The green host materials may include at least one of anthracene derivatives and carbazol compounds, but the embodiment is not limited thereto. For example, the anthracene derivatives may include 9,10-(2-dinaphthyl)anthracene (ADN), and the carbazol compounds may include 4,4′-(carbazol-9-yl) biphenyl(CBP). The green dopant material may include [Coumarin 6], Ir(PPy)3 (PPy=2-phenylpyridine), but the exemplary embodiments are not limited thereto.

The second light-emitting layer 151b may be formed by the same method as the first light-emitting layer 151a.

The third light-emitting layer 151c may be interposed between the hole transfer layer 163 and the buffer layer 152. The third light-emitting layer 151c may include fluorescent emission materials. For example, the third light-emitting layer 151c may include blue fluorescent emission materials, but the embodiment is not limited thereto. The third light-emitting layer 151c may contain other color fluorescent emission materials.

The third light-emitting layer 151c may be formed of polymer materials, low molecular organic materials, and/or mixtures of polymer and low molecular materials, which includes blue emission color. According to the exemplary embodiments, the third light-emitting layer 151c may include blue host materials and blue dopant materials.

The blue host materials may include at least one of anthracene derivatives and carbazol compounds, but the embodiment is not limited thereto. For example, the anthracene derivatives may include 9,10-(2-dinaphthyl)anthracene (ADN), and the carbazol compounds may include 4,4′-(carbazol-9-yl) biphenyl(CBP). The blue dopant material may include DPAVBi, DPAVBi derivative, distyrylarylene(DSA), distyrylarylene derivative, distyrylbenzene (DSB), distyrylbenzene derivative, spiro-DPVBi and spiro-6P, but the exemplary embodiments are not limited thereto.

The third light-emitting layer 151a may be formed by the same method as the first light-emitting layer 151a and the second light-emitting layer 151b.

FIG. 5 is a cross-sectional view of a display device manufactured by a donor substrate according to one or more exemplary embodiments.

Referring to FIG. 5, the buffer layer 152 may be disposed on the first light-emitting layer 151a, the second light-emitting layer 151b, and the third light-emitting layer 151c. Specifically, the buffer layer 152 may be interposed between the first light-emitting layer 151a, the second light-emitting layer 151b, and the third light-emitting layer 151c and an electronic transfer layer 153. The buffer layer 152 may be configured to aid supplying electrons to the first light-emitting layer 151a, the second light-emitting layer 151b, and the third light-emitting layer 151c. The buffer layer 152 may be disposed separately for respective pixels, or the buffer layer 152 may be formed as a single integrated layer throughout the entire surface of the insulation surface 160 as illustrated in FIG. 5. That is, the buffer layer 152 may be formed as a common layer unrelated with the distinction of pixels. The buffer layer 152 may be commonly formed on a plurality of pixel areas. Accordingly, the buffer layer 152 may be extended to the area between the first light-emitting layer 151a and the electron transfer layer 153, between the second light-emitting layer 151b and the electron transfer layer 153, and between the third light-emitting layer 151c and the electron transfer layer 153.

According to exemplary embodiments, the buffer layer 152 may include materials having high electron transfer attributes. For example, the buffer layer 153 may contain CBP and/or tris(8-quinolinolate)aluminum (Alq3).

The buffer layer 152 may have a thickness between about 30 Å and about 100 Å.

The buffer layer 152 having the thickness between about 30 Å and about 100 Å (wherein “about” means ±10%) may be configured to aid supplying of the electrons from the cathode 155 to the first light-emitting layer 151a, the second light-emitting layer 151b, and the third light-emitting layer 151c.

The electron transfer layer 153 may be disposed on the buffer layer 152. Specifically, the electron transfer layer 153 may be interposed between the buffer layer 152 and the electron injection layer 154. The electron transfer layer 153 may be disposed separately for respective pixels, or the electron transfer layer 153 may form bed as a single integrated layer throughout the entire surface of the insulation substrate 160 as illustrated in FIG. 5. That is, the electron transfer layer 153 may be formed as a common layer unrelated with the distinction of pixels. The electron transfer layer 153 may be commonly formed on a plurality of pixel areas.

The electron transfer layer 153 may include materials configured to transfer electrons injected from the cathode 155, which may include at least one of quinolin derivatives, particularly tris(8-quinolinolate)aluminum (Alq3), TAZ, Balq, and the like (hereinafter, called “host materials of the electron transfer layer 153”), but the embodiment is not limited thereto. The electron transfer layer 153 may be doped with at least one of metallic salt, metal oxide, and organic metallic salt (hereinafter, called “dopant materials of the electron transfer layer 153”). The metallic salt may include a halide of alkali metal and/or alkaline-earth metals, including LiF, NaF, KF, RbF, CsF, MgF2, CaF2, SrF2, BaF2, LiCl, NaCl, KCl, RbCl, CsCl, MgCl2, CaCl2, SrCl2, and BaCl2. The metal oxide may include alkali metal and/or oxide of alkali metal including LiO2, NaO2, BrO2, Cs2O, MgO, and CaO. The organic metallic salt may include Liq, Naq, and Kq represented by Formula 1 below.

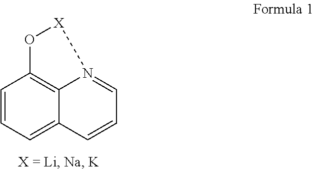

The electron transfer layer 153 and the buffer layer 152 may be formed in a single chamber. According to one or more exemplary embodiment, a first source including the host materials of the electron transfer layer 153, a second source including the dopant materials of the electron transfer layer 153, and a third source including the materials forming the buffer layer 152 may be arranged in the single chamber. The buffer layer 152 may be formed by opening the third source containing the material which forms the buffer layer 152, and the third source containing the materials forming the buffer layer 152 may be closed subsequently. The electron transfer layer 153 may be formed by simultaneously opening the first source including the host materials of the electron transfer layer 153 and the second source including the dopant materials of the electron transfer layer 153. For example, the three sources set may be moved to make two round trips between an one end of the insulation substrate 160 and the other end of the insulation substrate 160, i.e., four one way trips from the one end of the insulation substrate 160 to the other end of the insulation substrate 160 and vice versa. The third source containing the materials forming the buffer layer 152 may be opened while the first one way trip from the one end of the insulation substrate 160 to the other end of the insulation substrate 160 to form the buffer layer 152, and the first source containing the host materials of the electron transfer layer 153 and the second source containing the dopant materials of the electron transfer layer 153 may be opened while the last three one way trips between the one end of the insulation substrate 160 and the other end of the insulation substrate 160 to form the electron transfer layer 153. Therefore, the buffer layer 152 may be formed without a separate chamber, compared to corresponding competitive examples.

The electron injection layer 154 may be disposed on the electron transfer layer 153. Specifically, the electron injection layer 154 may be interposed between the electron transfer layer 153 and the cathode 155. The electron injection layer 154 may include any known electron injection materials. For example, the electron injection layer 154 may include at least one of LiF, NaCl, CsF, Li2O, BaO, etc., but the exemplary embodiments are not limited thereto.

The cathode 155 may be disposed on the electron injection layer 154. Specifically, the cathode 155 may be interposed between the electron injection layer 154 and the protection layer 156. The cathode 155 may include any conductive materials having a low work function. For example, the cathode may include at least one of Silver (Ag), Magnesium (Mg), Aluminum (Al), Platinum (Pt), Magnesium (Pd), Gold (Au), Nickel (Ni), Neodymium (Nd), Iridium (Ir), Chromium (Cr), Lithium (Li), Calcium (Ca), etc.

The protection layer 156 may be disposed on the upper surface of the cathode 155. The protection layer 156 may be configured to protect the laminated layers under the protection layer. The protection layer may include insulation materials. According to exemplary embodiments, a spacer (not shown) may be arranged between the cathode 155 and the protection layer 156. According to exemplary embodiments, the protection layer 156 may be omitted.

Referring to FIG. 5, a display device may include auxiliary layers having different thicknesses for respective pixel areas.

FIG. 6 is a cross-sectional view of a donor substrate, according to one or more exemplary embodiments.

The donor substrate of FIG. 6 is similar to the donor substrate 100 illustrated in FIG. 1. The donor substrate illustrated in FIG. 6 is different from the donor substrate 100 illustrated in FIG. 1 in that it may include a reflection pattern layer 120. The reflection pattern layer 120 may be disposed on a light-transmitting base substrate 110 and include an opening 120a. The insulation layer 130 may be disposed covering the upper surface of the reflection pattern layer 120 and may be disposed in the opening 120a covering a surface of the light-transmitting base layer 110 exposed by the opening 120a.

The lamp light or lase light transmitted through the light-transmitting base substrate 110 is reflected by the reflection pattern layer 120 except for where the opening 120a is formed. The lamp light or laser light radiated toward the opening 120a, may be transmitted through the opening 120a without being reflected. The lamp light or laser light transmitted through the opening 120a of the reflection pattern layer 120 may reach an area of the absorption layer 140 that corresponds with the opening 120a.

A reflection plate (Not shown) may be additionally disposed on the back surface of the light source to reflect the lamp light or laser light reflected by the reflection pattern layer 120 toward the light-transmitting base substrate, back toward the reflection pattern layer 120.

The reflection pattern layer 120 may include at least one of materials having high reflectivity to the lamp light or laser light, such as aluminum (Al), silver (Ag), gold (Au), platinum (Pt), copper (Cu), an aluminum alloy, a silver alloy, indium oxide, and tin oxide. The reflection pattern layer 120 may be formed by depositing the materials using the sputtering method, the electronic beam deposition method, the vacuum deposition method, etc., and patterning the deposited materials.

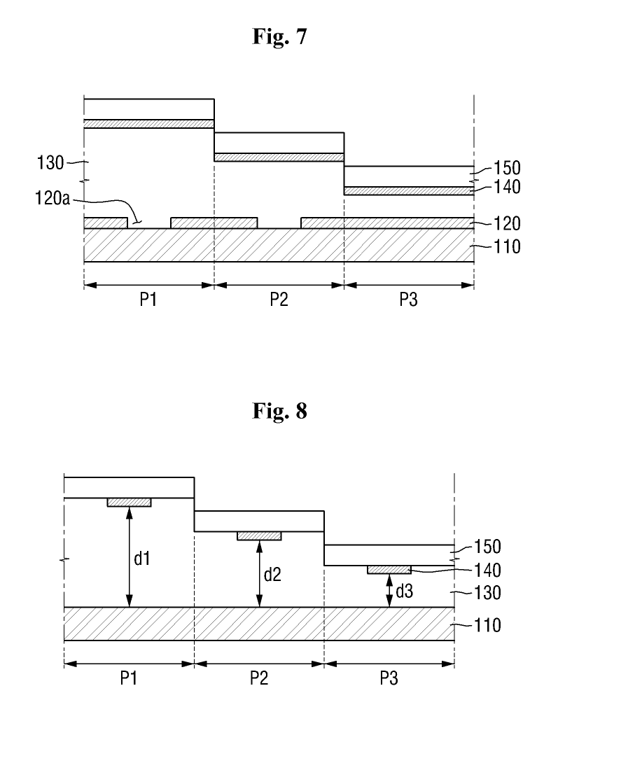

FIG. 7 is a cross-sectional view of a donor substrate according to one or more exemplary embodiments.

The donor substrate illustrated in FIG. 7 is similar to the donor substrate illustrated in FIG. 6. The donor substrate of FIG. 7 is different from the donor substrate of FIG. 6 in that the opening 120a may be omitted in the reflection pattern layer 120 disposed in the third area P3. Referring to FIG. 7, the reflection pattern layer 120 disposed on the third area P3 may reflect the lamp light or laser light transmitted through the light-transmitting base substrate 110. In this case, the absorption layer 140 disposed in the third area P3 does not generate heat, and the heat energy is not transmitted to the transfer layer 150. As a result, the transfer layer 150 disposed in the third area P3 is not sublimated, and may remain on the absorption layer 140.

FIG. 8 is a cross-sectional view illustrating a donor substrate according to one or more exemplary embodiments.

The donor substrate illustrated in FIG. 8 is similar to the donor substrate 100 illustrated in FIG. 1. The donor substrate illustrated in FIG. 8 is different from the donor substrate 100 illustrated in FIG. 1 in that the absorption layer 140 does not cover the entire upper surface of the insulation layer 130, and the absorption layer 140 is disposed in a concave groove on the top surface of the insulation layer 130. Referring to FIG. 8, the absorption layer 140 may be disposed in a concave groove on the tip surface of the insulation layer 130, and the absorption may not be projected, thus the upper surface of the absorption layer 140 may have the same height as that of the insulation layer 130 in the area where the absorption layer 140 is not disposed.

Most of the heat energy generated in the absorption layer 140 may be transmitted to the transfer layer 150 and selectively sublimate to apply the transfer layer 150. The transfer layer which overlaps the absorption layer 140 may be sublimated toward the insulation layer 160.

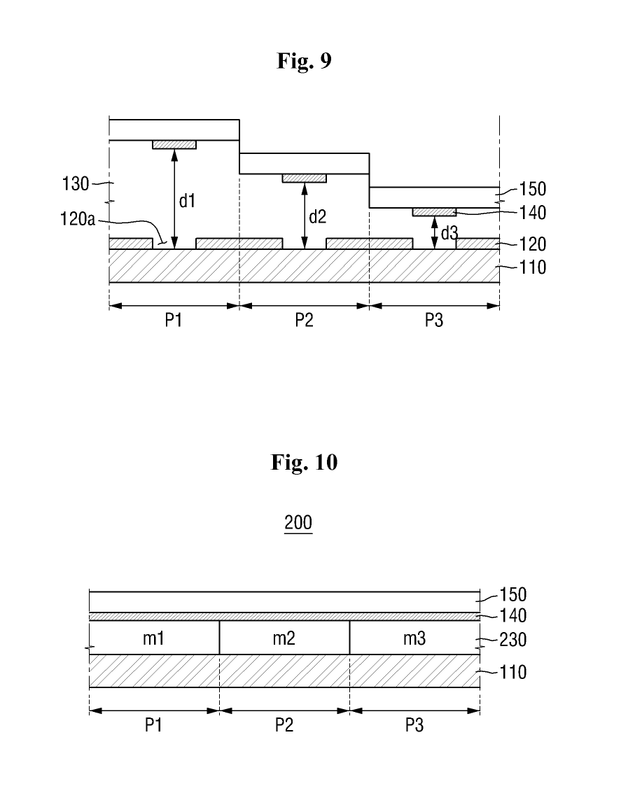

FIG. 9 is a cross-sectional view of a donor substrate according to one or more exemplary embodiments.

The donor substrate illustrated in FIG. 9 is similar to the donor substrate illustrated in FIG. 8. The donor substrate in FIG. 9 is different from the donor substrate illustrated in FIG. 8 that in the donor substrate in FIG. 9 includes a reflection pattern layer 120. The reflection pattern layer 120 is disposed on the light-transmitting base substrate 110 and includes an opening 120a. The reflection pattern layer 120 and the opening have been previously described in connection with the donor substrate illustrated in FIG. 7, and thus the description thereof is omitted.

Referring to FIG. 10, the donor substrate 200 according to one or more exemplary embodiments may include a light-transmitting base substrate 110, an insulation layer 230, an absorption layer 140, and a transfer layer 150. The donor substrate 200 may have the similar configuration as that of the donor substrate 100 of FIG. 1 except for the inclusion of insulation layer 230. Hence, the repeated description is omitted here, and only the insulation layer 230 will be described here.

The insulation layer 230 is disposed on one surface of the light-transmitting base substrate 110. The insulation layer 230 is divided into three areas P1, P2, and P3. The insulation layer 230 may include a first material m1 in the first area P1, may include a second material m2, different from the first material m1, in the second area P2, and may include a third material m3, different from the first material m1 and the second material m2, in the third area P3.

The first material m1, the second material m2, and the third material m3 may have different thermal conductivities. Specifically, the first material m1 disposed in the first area P1 may have a lower thermal conductivity compared to the second material m2 and the third material m3. The second material m2 disposed in the second area P2 may have a higher thermal conductivity compared to the first material m1 and a lower thermal conductivity compared to the third material m3. The third material m3 disposed in the third area P3 may have a higher thermal conductivity compared to the first material m1 and the second material m2.

The upper surfaces of the insulation layer 230 may be flat and may have the same heights in the first to third areas P1, P2, and P3. Specifically, the upper surface of the insulation layer 130 formed on the first area P1, the upper surface of the insulation layer 130 formed on the second area P2, and the upper surface of the insulation layer 130 formed on the third area P3 may be the same.

The first material m1 included in the insulation layer 230 disposed in the first area P1 may include organic polymer and/or high heat-resistant organic materials. The organic polymer and/or high heat-resistant organic materials may include at least one of polyamide (PI) and polyacryl (PA). The second material m2 included in the insulation layer 230 disposed in the second area P2 may include at least one of titanium oxide, silicon oxide, silicon nitride oxide, zirconium oxide, silicon carbide, silicon oxide, silicon nitride, and an organic polymer. The third material m3 included in the insulation layer 230 disposed in the third area P3 may include at least one of aluminum (Al), silver (Ag), gold (Au), platinum (Pt), copper (Cu), an aluminum alloy, a silver alloy, and indium oxide-tin oxide. The insulation layer 230 may be formed by a sputtering method, an electronic beam deposition method, a vacuum deposition method, etc.

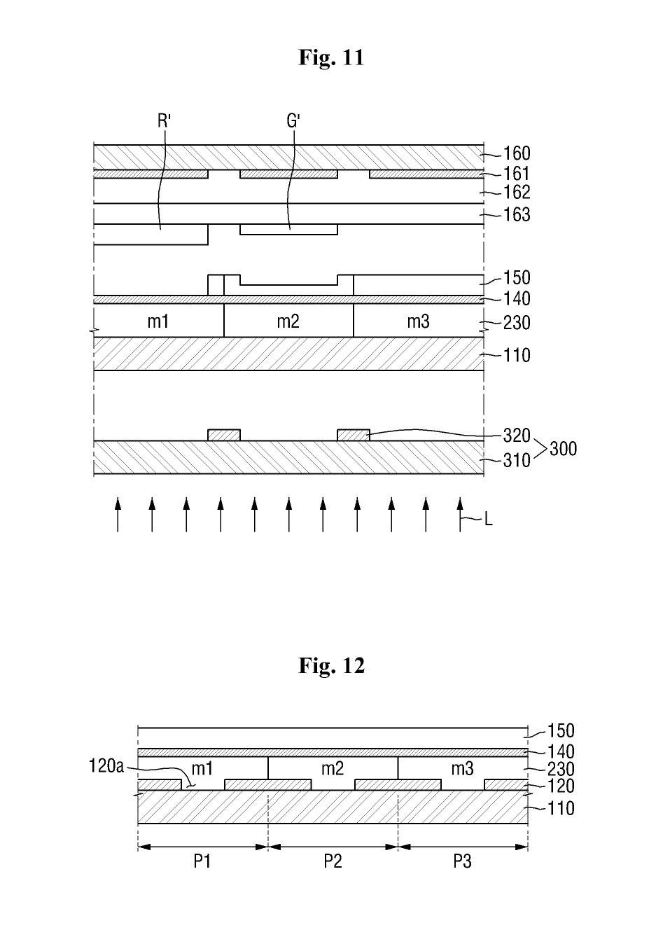

FIG. 11 is a cross-sectional view illustrating a method of manufacturing a display device using the donor substrate 200 illustrated in FIG. 10 according to one or more exemplary embodiments.

The method illustrated in FIG. 11 is the same with the method illustrated in the FIG. 3 except for the insulation layer 230. Hence, with respect to the method of manufacturing a display device by using a donor substrate 200 according to one or more exemplary embodiments, only the insulation layer 230 will be described.

The light L radiated from the lower surface of the light-transmitting base substrate 110, may be sequentially incident on the optical mask 300, the light-transmitting base substrate 110, the insulation layer 230, and the absorption layer 140. The light L may be radiated onto the absorption layer 140, and the absorption layer is configured to generate heat. The heat energy generated in the absorption layer 140 may be insulated by the insulation layer 230, and the heat energy may be transmitted to the transfer layer 150.

The insulation layer 230, disposed in the first area P1 may include a first material m1 having a lower thermal conductivity compared to the insulation layer 230 disposed in the second area P2 and the third area P3, and thus the insulation effect may be higher in the insulation layer 230 disposed in the first area P1 compared to the insulation layer 230 disposed in the second area P2 and the third area P3. Hence, the heat energy transmitted to the transfer layer 150 may be greater in the first area P1 than in the second area P2 and the third area P3, and more transfer layer 150 may be sublimated in the first area P1 than in the second area P2 and the third area P3.

The insulation layer 230, disposed in the second area P2, may include a second material m2 having a higher thermal conductivity compared to the insulation layer 230 disposed in the first area P1, and thus, may have smaller insulation effect compared to the insulation layer 230 disposed in the first area P1. Hence, the heat energy transmitted to the transfer layer 150 may be less in the second area P2 compared to the first area P1, and less transfer layer 150 may be sublimated in the second area P2 compared to the first area P1.

In the same manner, the insulation layer 230 disposed in the third area P3 may have less insulation effect compared to the insulation layer 230 disposed in the first area P1 and the second area P2, and less transfer layer 150 may be sublimated in the third area P3 compared to the first area P1 and the second area P2.

Referring to FIG. 9, when the heat energy transmitted to the transfer layer 150 disposed in the third area P3 is not enough to sublimate the transfer layer 150, the transfer layer 150 may not be sublimated.

The transfer layer 150 sublimated in the three areas P1, P2, and P3 may be deposited onto the insulation substrate 160 and form an organic material layer, specifically, auxiliary layers R′ and G′. The first auxiliary layer R′ deposited in the first area P1, where more transfer layer 150 may be sublimated than the second and third areas P2 and P3, may have the largest thickness, and the second auxiliary layer G′ deposited in the second area P2, where less transfer layer 150 may be sublimated than in the first area P1, may have smaller thickness compare to the first auxiliary layer R′. The deposited thickness in the third area P3, where less transfer layer 150 may be sublimated than the first area P1 and the second area P2, may be the smallest. The deposition in the third area P3 may not occur when the transfer layer 150 is not sublimated in the third area P3 as described above.

According to the one or more exemplary embodiments, a donor substrate may include the insulation layer having differential thermal conductivities for respective areas, and auxiliary layers having different thicknesses may be deposited in a single process by using the donor substrate.

FIG. 12 is a cross-sectional view of a donor substrate according to one or more exemplary embodiments. The donor substrate illustrated in FIG. 12 is similar to the donor substrate 200 illustrated in FIG. 10. The donor substrate may include a reflection pattern layer 120.

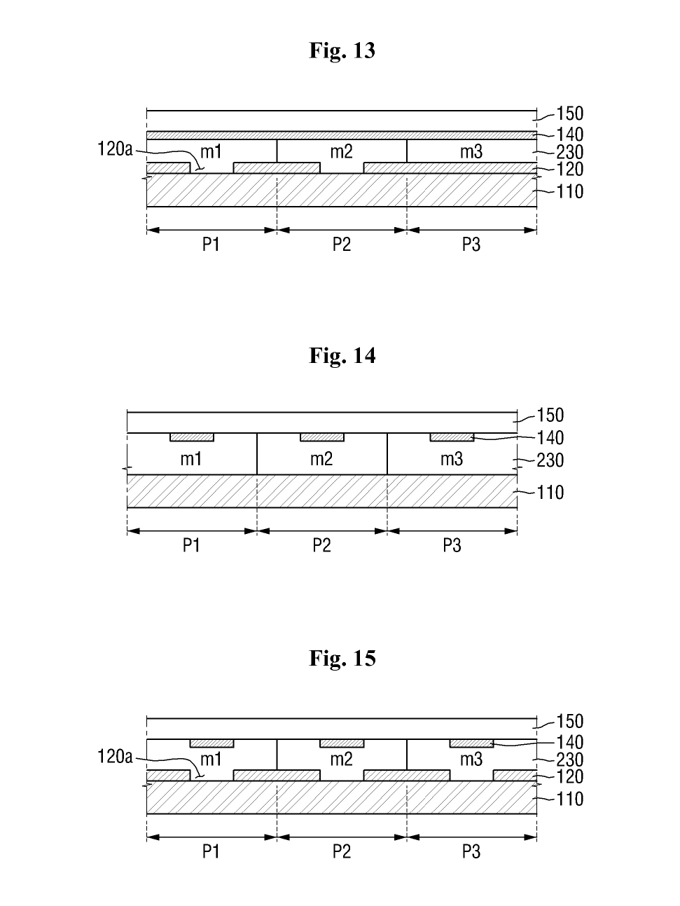

FIG. 13 is a cross-sectional view of a donor substrate according to one or more exemplary embodiments. The donor substrate illustrated in FIG. 13 is similar to the donor substrate illustrated in FIG. 12. The donor substrate may be different from the donor substrate of FIG. 12 in that the opening 120a may be omitted in the flection pattern layer 120 disposed in the third area P3.

FIG. 14 is a cross-sectional view of a donor substrate according to one or more exemplary embodiments. The donor substrate illustrated in FIG. 14 is similar to the donor substrate 200 illustrated in FIG. 10. Only, they are different in that in the donor substrate of FIG. 14, the absorption layer 140 does not cover the entire upper surface of the insulation layer 130, and the absorption layer 140 is disposed in a concave groove on the top surface of the insulation layer 130.

FIG. 15 is a cross-sectional view of a donor substrate according to one or more exemplary embodiments. The donor substrate illustrated in FIG. 15 is similar to the donor substrate illustrated in FIG. 14. The donor substrate may include a reflection pattern layer 120.

According to the one or more exemplary embodiments, an insulation substrate having different thicknesses may be deposited in a single process by using a donor substrate according to the one or more exemplary embodiments.

Although certain exemplary embodiments and implementations have been described herein, other embodiments and modifications will be apparent from this description. Accordingly, the inventive concept is not limited to such embodiments, but rather to the broader scope of the presented claims and various obvious modifications and equivalent arrangements.

What is claimed is:

1. A donor substrate, comprising:
a light-transmitting base substrate;
an insulation layer disposed on an upper surface of the light-transmitting base substrate, the insulating layer comprising:
a first area having a first thickness;
a second area having a second thickness, the second thickness different from the first thickness; and
a third area having a third thickness, the third thickness different from the first thickness and the second thickness;
an absorption layer disposed on the insulation layer; and
a transfer layer disposed on the absorption layer.

2. The donor substrate of claim 1, wherein the first thickness of the first area of the insulation layer is greater than the second thickness of the second area of the insulation layer, and the second thickness of the second area of the insulation layer is greater than the third thickness of the third area of the insulation layer.

3. The donor substrate of claim 1, wherein the insulation layer comprises:
a first step disposed on an upper surface of the insulation layer between the first area and the second area; and
a second step disposed on the upper surface of the insulation layer between the second area and the third area.

4. The donor substrate of claim 1, wherein the insulation layer comprises at least one of titanium oxide, silicon oxide, silicon nitride oxide, zirconium oxide, silicon carbide, silicon oxide, silicon nitride, and an organic polymer.

5. The donor substrate of claim 1, wherein the absorption layer is configured to convert incident light into heat energy.

6. A donor substrate comprising:
a light-transmitting base substrate;
an insulation layer disposed on an upper surface of the light-transmitting base substrate, the insulating layer comprising:
a first area comprising a first material;
a second area comprising a second material, the second material different from the first material; and
a third area comprising a third material, the third material different from the first material and the second material;
an absorption layer disposed on the insulation layer; and
a transfer layer disposed on the absorption layer.

7. The donor substrate of claim 6, wherein a thermal conductivity of the first material is lower than a thermal conductivity of the second material, and the thermal conductivity of the second material is lower than a thermal conductivity of the third material.

8. The donor substrate of claim 7, wherein the first material of the insulation layer in the first area comprises one of an organic polymer or a high heat-resistant organic material.

9. The donor substrate of claim 8, wherein the organic polymer or the high heat-resistant organic material comprises at least one of polyimide (PI) and polyacryl (PA).

10. The donor substrate of claim 7, wherein the second material of the insulation layer comprises at least one of titanium oxide, silicon oxide, silicon nitride oxide, zirconium oxide, silicon carbide, silicon oxide, silicon nitride, and an organic polymer.

11. The donor substrate of claim 7, wherein the third material of the insulation layer comprises at least one of aluminum, silver, gold, platinum, copper, an alloy containing aluminum, an alloy containing silver, indium oxide, and tin oxide.

12. The donor substrate of claim 12, wherein the absorption layer is configured to convert incident light into heat energy.

13. A method of manufacturing a display device, the method comprising:
preparing a donor substrate comprising:
a light-transmitting base substrate;
an insulation layer disposed on an upper surface of the light-transmitting base substrate, the insulating layer comprising:
a first area having a first thickness;
a second area having a second thickness, the second thickness different from the first thickness; and
a third area having a third thickness, the third thickness different from the first thickness and the second thickness;
an absorption layer disposed on the insulation layer; and
a transfer layer disposed on the absorption layer,
disposing a pixel insulation substrate facing an upper surface of the donor substrate; and
depositing at least a part of the transfer layer onto the pixel insulation substrate to form an auxiliary layer by radiating light through a lower surface of the light-transmitting base substrate.

14. The method of claim 13, further comprising:
disposing an optical mask at a lower surface of the light-transmitting base substrate, the optical mask comprising a shade part and a mask base.

15. The method of claim 13, wherein the first thickness of the first area of the insulating layer is greater than the second thickness of the second area of the insulating layer, and the second thickness of the second area of the insulating layer is greater than the third thickness of the third area of the insulating layer.

16. The method of claim 15, wherein the depositing at least a part of the transfer layer onto the pixel insulation substrate to form the auxiliary layer comprises:
depositing a first auxiliary layer corresponding to the first area, the first auxiliary layer having a first deposition thickness;
depositing a second auxiliary layer corresponding to the second area, the second auxiliary layer having a second deposition thickness, the second deposition thickness smaller than the first deposition thickness; and
depositing a third auxiliary layer corresponding to the third area, the third auxiliary layer having a third deposition thickness, the third deposition thickness smaller than the second deposition thickness.

17. The method of claim 16, wherein the third deposition thickness is substantially 0.

18. The method of claim 13, wherein the insulation layer comprises:
a first step disposed on an upper surface of the insulation layer between the first area and the second area; and
a second step disposed on the upper surface of the insulation layer between the second area and the third area.

19. The method of claim 13, wherein the insulation layer comprises at least one of titanium oxide, silicon oxide, silicon nitride oxide, zirconium oxide, silicon carbide, silicon oxide, silicon nitride, and an organic polymer.

20. The method of claim 13, wherein the absorption layer is configured to convert incident light into heat energy.
